(19) United States
(12) Patent Application Publication
(10) Pub. No.: US 2013/0337192 A1
(43) Pub. Date: Dec. 19, 2013

(54) BIS-PYRROLES-2-ALDIMINATE MANGANESE PRECURSORS FOR DEPOSITION OF MANGANESE CONTAINING FILMS

(71) Applicant: L'Air Liquide, Societe Anonyme Pour I'Etude et I'Exploitation des Procedes Georges Claude, Paris (FR)

(72) Inventor: Clément Lansalot-Matras, Seoul (KR)

(73) Assignee: L'Air Liquide Société Anonyme pour I'Etude et I'Exploitation des Procédés Georges Claude, Paris (FR)

(21) Appl. No.: 13/875,208

(22) PCT Filed: Nov. 3, 2011
(86) PCT No.: PCT/IB2011/054898

§ 371 Date: Sep. 3, 2013

Related U.S. Application Data
(60) Provisional application No. 61/409,841, filed on Nov. 3, 2010.
(60) Provisional application No. 61/410,582, filed on Nov. 5, 2010.

(51) Int. Cl. H01L 21/768

(52) U.S. Cl. CPC H01L 21/76841
USPC 427/569; 548/108; 427/96.8

(57) ABSTRACT

Disclosed are manganese-containing precursors having the formula (I): wherein each R¹ through R⁵ is independently selected from H; C₁-C₄ linear or branched alkyl group; C₁-C₄ linear, branched, or cyclic alkylsilyl group; C₁-C₄ alkylamino group; and a C₁-C₄ linear or branched fluoroalkyl group. Also disclosed are method of making the disclosed manganese-containing precursors and methods of using the disclosed manganese-containing precursors to deposit Mn-containing films on a substrate.

### CROSS-REFERENCE TO RELATED APPLICATIONS

This application claims the benefit of U.S. Provisional Application Nos. 61/409,841, filed Nov. 3, 2010, and 61/410,582, filed Nov. 5, 2010, the entire contents of each being incorporated herein by reference.

### TECHNICAL FIELD

Disclosed are bis pyrroles-2-aldiminate manganese complexes and methods of making the same. Also disclosed are methods of using the disclosed complexes in the deposition of manganese-containing films via Atomic Layer Deposition (ALD) or Chemical Vapor Deposition (CVD).

### BACKGROUND

There has been a considerable concern about the performance and reliability of Cu interconnect structure for the technology nodes of 32 nm and beyond in ultra large scale integrated circuits (ULSI). The advanced technology nodes require a uniform barrier thickness of less than 5 nm with a good diffusion barrier property as well as good adhesion to Cu. Weak adhesion between the chemical-mechanical polished copper surface and the dielectric capping material can lead to rapid electromigration of Cu and early failure of the wiring. However, conventional physical vapor deposition (PVD) processes have encountered difficulties mainly because of poor step coverage.

To overcome these problems, a self-formed MnSiₓO_{y} diffusion barrier layer that uses a Cu—Mn alloy was proposed to strengthen the interface between Cu and dielectric insulators without increasing the resistivity of Cu. The manganese penetrates only a few nanometers into the silica to make conformal amorphous manganese silicate layers. The MnOₓ and MnSiₓO_{y} phases were found to be an excellent barrier to the diffusion of Cu, O₂ and H₂O vapor.

As an element of the 7^{th} column of the periodic table, deposition of manganese containing films has remained challenging because of low thermal stability of the manganese source. As a result, few thermally stable and volatile manganese precursors are available for CVD or ALD processes.

Manganese bis 2,2,6,6-tetramethylheptadionate (Mn(tmhd)₂) (Nilsen Thin Solid Films 444 (2003) 44-51; Nilsen, Thin Solid Films 468 (2004) 65-74) and manganese bis cyclopentadienyl (MnCp₂, Mn(Me₄Cp)₂) (Burton, Thin Solid Films 517 (2009) 5658-5665; Holme, Solid State Ionics 179 (2008) 1540-1544; Neishi, Mater. Res. Soc. Symp. Proc. Vol. 1156) for instance have been successfully used for the deposition of MnOₓ by CVD or ALD.

Manganese bis amidinate has also been used for the deposition of manganese containing films (MnSiₓO_{y}) (Gordon, Advanced Metallization Conference 2008; Gordon, J. Electrochem. Soc., Volume 157, Issue 6, pp. D341-D345 (2010)).

Manganese bis(2-pyrrolealdehyde) ethylenediimine or phenylenediimine have been prepared. Synthesis is however described using Mn₃(Mes)₆ (Mes=2,4,6-trimethylphenyl) as the starting material and may lead to a dimer precursor (having two compounds in the same molecule), such as in the case of ethylenediamine (NH₂CH₂CH₂NH₂)(Pui, Aurel; Cecal, Alexandru; Drochioiu, Gabi; Pui, Mihaela. Revue Roumaine de Chimie (2003), 48(6), 439-443; Franceschi, Federico; Guillemot, Geoffroy; Solari, Euro; Floriani, Carlo; Re, Nazzareno; Birkedal, Henrik; Pattison, Philip. Chemistry—A European Journal (2001), 7(7), 1468-1478).

Bis pyrrole-2-aldiminate metal precursors (metal=Fe, Co, Ni, Cu, Ru, Rh, Pd, Pt) have been considered for the deposition of pure metal films.

Other thermally stable manganese sources and methods of incorporating such materials are being sought for new generations of integrated circuit devices.

### SUMMARY

Disclosed is a process for the deposition of a manganese-containing film on a substrate. A reactor is provided having at least one substrate disposed therein. The vapor of at least one manganese-containing precursor is introduced into the reactor. The manganese-containing precursor has the formula:

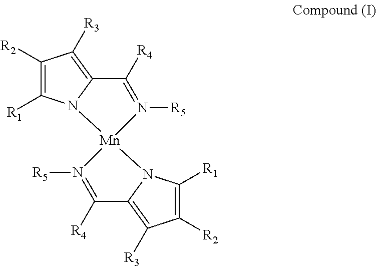

wherein each R¹ through R⁵ is independently selected from H; C₁-C₄ linear or branched alkyl group; C₁-C₄ linear, branched, or cyclic alkylsilyl group; C₁-C₄ alkylamino group; and a C₁-C₄ linear, branched, or cyclic fluoroalkyl group. At least part of the vapor is deposited onto the substrate to form the manganese-containing film. The disclosed methods may include one or more of the following aspects:
maintaining the reactor at a temperature between about 100° C. to about 500° C.;
maintained the reactor at a temperature between about 150° C. and about 350° C.;
maintaining the reactor at a pressure between about 1 Pa and about 10⁵ Pa;
maintaining the reactor at a pressure between about 25 Pa and about 10³ Pa;
the manganese-containing precursor being selected from the group consisting of:
   Bis 2-iminemethylpyrrolyl manganese(II)
   Bis 2-methyliminemethylpyrrolyl manganese(II)
   Bis 2-ethyliminemethylpyrrolyl manganese(II)
   Bis 2-isopropyliminemethylpyrrolyl manganese(II)
   Bis 2-npropyliminemethylpyrrolyl manganese(II)
   Bis 2-nbutyliminemethylpyrrolyl manganese(II)
   Bis 2-secbutyliminemethylpyrrolyl manganese(II)
   Bis 2-isobutyliminemethylpyrrolyl manganese(II)
   Bis 2-tertbutyliminemethylpyrrolyl manganese(II) and
   Bis 2-trimethylsilylbutyliminemethylpyrrolyl manganese(II);
the manganese-containing precursor being bis 2-isopropyliminemethylpyrrolyl manganese (II);
introducing at least one reactant into the reactor;
the reactant being selected from the group consisting of H₂; NH₃; SiH₄; Si₂H₆; Si₃H₈; SiH₂Me₂, SiH₂Et₂, N(SiH₃)₃, hydrogen radicals; and mixtures thereof;
the reactant being selected from the group consisting of: O₂; O₃; H₂O; NO; N₂O, oxygen radicals; and mixtures thereof;
introducing the manganese-containing precursor and the reactant into the chamber substantially simultaneously, and the chamber being configured for chemical vapor deposition;
introducing the manganese-containing precursor and the reactant into the chamber sequentially, and the chamber being configured for atomic layer deposition; and
the chamber being configured for either plasma enhanced atomic layer deposition or plasma enhanced chemical vapor deposition.

Also disclosed are methods of synthesizing a manganese-containing precursor having the structure:

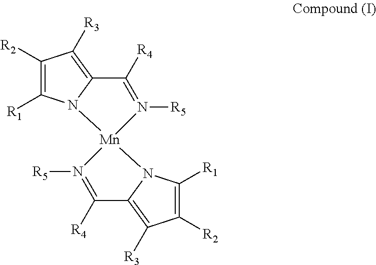

wherein each R¹-R⁵ is independently selected from H; C₁-C₄ linear or branched alkyl group; C₁-C₄ linear, branched, or cyclic alkylsilyl group; C₁-C₄ alkylamino group; and C₁-C₄ linear or branched fluoroalkyl group.

In one embodiment MnX₂, with X=Cl, Br, I or F, is reacted with 2 equivalents of Z-L, wherein Z=Li, Na, K, and Tl and L=pyrroles-2-aldiminate ligand according to Scheme-1.

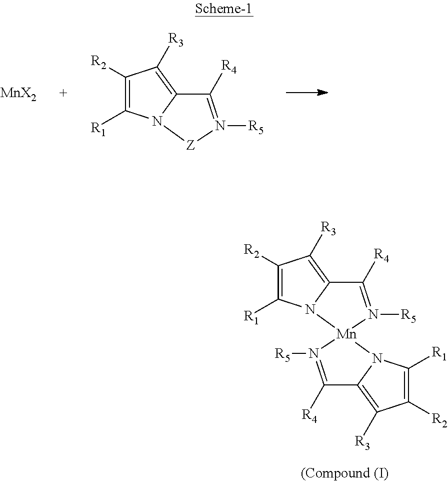

In a second embodiment, MnX₂, with X=OAc, OMe, OEt, is reacted with 2 equivalents of pyrroles-2-aldiminate ligand according to Scheme-2.

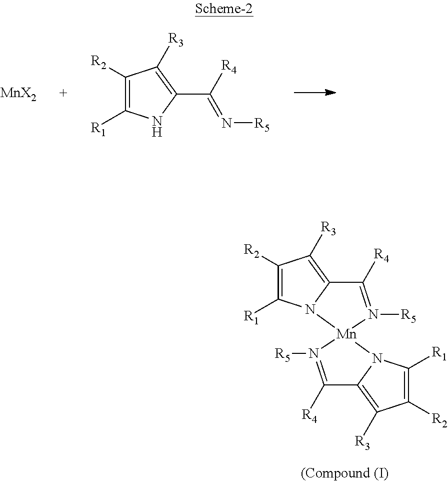

The disclosed methods may include one or more of the following aspects:
the reacting step occurring in a polar solvent;
removing the polar solvent;
forming a solution by adding a second solvent selected from the group consisting of pentane, hexane, benzene, and toluene;
filtering the solution;
removing the second solvent to form the manganese-containing precursor; and
distilling or sublimating the manganese-containing precursor.

### NOTATION AND NOMENCLATURE

Certain abbreviations, symbols, and terms are used throughout the following description and claims and include:

The standard abbreviations of the elements from the periodic table of elements are used herein. It should be understood that elements may be referred to by these abbreviations (e.g., Mn refers to manganese, Tl refers to thallium, etc).

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎ where x is 2 or 3, the two or three R¹ groups may, but need not be identical to each other or to R² or to R³. Further, it should be understood that unless specifically stated otherwise, values of R groups are independent of each other when used in different formulas.

The term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “Pr,” refers to a propyl group; the abbreviation, “iPr,” refers to an isopropyl group; the abbreviation “Bu” refers to butyl (n-butyl); the abbreviation “tBu” refers to tert-butyl; the abbreviation “sBu” refers to sec-butyl; the abbreviation “acac” refers to acetylacetonate; the abbreviation “tmhd” refers to 2,2,6,6-tetramethyl-3,5-heptadionato; the abbreviation “od” refers to 2,4-octadionato; the abbreviation “mhd” refers to 2-methyl-3,5-hexadinonato; the abbreviation “tmod” refers to 2,2,6,6-tetramethyl-3,5-octanedionato; the abbreviation “ibpm” refers to 2,2,6-trimethyl-3-5-heptadionato; the abbreviation “hfac” refers to hexafluoroacetylacetonato; the abbreviation “tfac” refers to trifluoroacetylacetonato; the abbreviation “Cp” refers to cyclopentadienyl; the abbreviation “Cp*” refers to pentamethylcyclopentadienyl; the abbreviation “op” refers to (open)pentadienyl; the abbreviation “cod” refers to cyclooctadiene; the abbreviation “dkti” refers to diketiminate (whatever the R ligand bonded to the nitrogen atoms); the abbreviation “emk” refers to enaminoketonate (whatever the R ligand bonded to the nitrogen atom); the abbreviation “amd” refers to amidinate (whatever the R ligand on the nitrogen atoms); the abbreviation “formd” refers to formamidinate (whatever the R ligand on the nitrogen atoms); the abbreviation “dab” refers to diazabutadiene (whatever the R ligand on the nitrogen atom).

For a better understanding, the generic structures of some of these ligands are represented below, wherein each R is independently selected from H; a C₁-C₆ linear, branched, or cyclic alkyl or aryl group; an amino substituent such as NR¹R² or NR¹R²R³, wherein R¹, R², and R³ are independently selected from H or a C₁-C₆ linear, branched, or cyclic alkyl or aryl group; and an alkoxy substituent such as OR, or OR¹R² wherein R¹ and R² are independently selected from H and a C₁-C₆ linear, branched, or cyclic alkyl or aryl group.

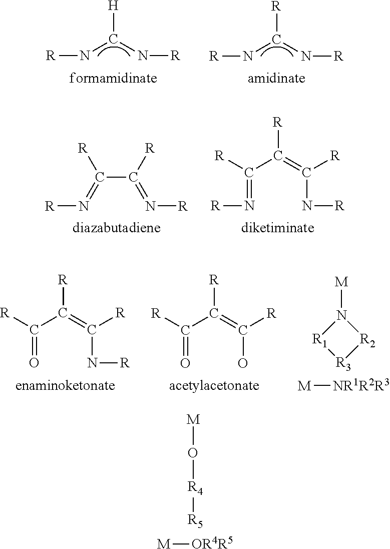

### BRIEF DESCRIPTION OF THE DRAWINGS

For a further understanding of the nature and objects of the present invention, reference should be made to the following detailed description, taken in conjunction with the accompanying graphs, and wherein:

FIG. 1 is an atmospheric and vacuum thermogravimetric analysis (TGA) graph of bis 2-methyliminemethylpyrrolyl manganese(II);

FIG. 2 is an atmospheric and vacuum thermogravimetric analysis (TGA) graph of bis 2-ethyliminemethylpyrrolyl manganese(II);

FIG. 3 is an atmospheric and vacuum thermogravimetric analysis (TGA) graph of bis 2-isopropyliminemethylpyrrolyl manganese(II);

FIG. 4 is an atmospheric and vacuum thermogravimetric analysis (TGA) graph of bis 2-tertbutyliminemethylpyrrolyl manganese(II);

FIG. 5 is a vapor pressure graph for the bis pyrroles-2-methylaldiminate manganese(II) precursors of FIGS. 1-4.

### DESCRIPTION OF PREFERRED EMBODIMENTS

Disclosed are manganese-containing precursors having the formula:

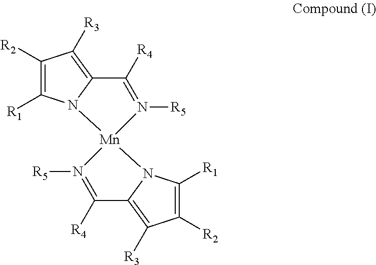

wherein R₁ through R₅ are independently selected from H; C₁-C₄ linear or branched alkyl group; C₁-C₄ linear, branched, or cyclic alkylsilyl group; C₁-C₄ linear, branched, or cyclic alkylamino group; or a C₁-C₄ linear or branched fluoroalkyl group. The alkylsilyl group may comprise a mono, bis, or trisalkyl group (i.e. methylsilyl, dimethylsilyl, trimethylsilyl). The fluorination of the fluoroalkyl group may range from partially fluorinated, with one F molecule in the group, to fully fluorinated, with a F molecule on each available position in the alkyl group (i.e. with no H substituents).

Embodiments of the disclosed manganese-containing precursors include:

Bis 2-alkylimine-1-alkylmethyl-tri-alkylpyrrolyl manganese(II) (R₁ through R₅=alkyl, with each alkyl independently being a linear or branched C₁ to C₄, such as Me, iPr, etc.)

Bis 2-alkylaminoiminemethyl-tri-alkylaminopyrrolyl manganese(II) (R₁ through R₃ & R₅=alkylamino, R₄=H, with each alkylamino independently being a linear, branched or cyclic C₁ to C₄ alkylamino, such as methylamino, methylethylamino, isopropylamino, cyclobutylamino, etc.)

Bis 2-fluoroalkyliminemethyl-tri-fluoroalkylpyrrolyl manganese(II) (R₁ through R₃ & R₅=fluoroalkyl, R₄=H, with each fluoroalkyl being C₁ to C₄ fluoroalkyl, such as nonafluorobutyl, fluoromethyl, difluoropropyl, etc.)

The disclosed manganese-containing precursors enable the deposition of pure manganese films or manganese-containing films depending on the co-reactant used with the precursor, whose resulting films are deposited without detectable incubation time, and for which an ALD regime can be obtained for pure manganese deposition as well as for deposition of other manganese containing films (MnOₓ as an example).

Exemplary manganese-containing precursors are listed below by alphabetical indicator, which is listed with the corresponding chemical structure following the list:
A: Bis iminemethylpyrrolyl manganese(II)
B: Bis 2-methyliminemethylpyrrolyl manganese(II)
C: Bis 2-ethyliminemethylpyrrolyl manganese(II)
D: Bis 2-isopropyliminemethylpyrrolyl manganese(II)
E: Bis 2-npropyliminemethylpyrrolyl manganese(II)
F: Bis 2-nbutyliminemethylpyrrolyl manganese(II)
G: Bis 2-secbutyliminemethylpyrrolyl manganese(II)
H: Bis 2-isobutyliminemethylpyrrolyl manganese(II)
I: Bis 2-tertbutyliminemethylpyrrolyl manganese(II)
J: Bis 2-acetimidoylpyrrolyl manganese(II)
K: Bis 2-N-methylacetimidoylpyrrolyl manganese(II)
L: Bis 2-N-ethylacetimidoylpyrrolyl manganese(II)
M: Bis 2-N-isopropylacetimidoylpyrrolyl manganese(II)
N: Bis 2-N-npropylacetimidoylpyrrolyl manganese(II)
O: Bis 2-N-nbutylacetimidoylpyrrolyl manganese(II)
P: Bis 2-N-secbutylacetimidoylpyrrolyl manganese(II)
Q: Bis 2-N-isobutylacetimidoylpyrrolyl manganese(II)
R: Bis 2-N-tertbutylacetimidoylpyrrolyl manganese(II)
S: Bis 2-iminemethyl-5-methylpyrrolyl manganese(II)
T: Bis 2-methyliminemethyl-5-methylpyrrolyl manganese(II)
U: Bis 2-ethyliminemethyl-5-methylpyrrolyl manganese(II)
V: Bis 2-isopropyliminemethyl-5-methylpyrrolyl manganese(II)
W: Bis 2-npropyliminemethyl-5-methylpyrrolyl manganese(II)
X: Bis 2-nbutyliminemethyl-5-methylpyrrolyl manganese(II)
Y: Bis 2-secbutyliminemethyl-5-methylpyrrolyl manganese(II)
Z: Bis 2-isobutyliminemethyl-5-methylpyrrolyl manganese(II)
AA: Bis 2-tertbutyliminemethyl-5-methylpyrrolyl manganese(II)
AB: (2-iminemethylpyrrolyl)(2-methyliminemethylpyrrolyl)manganese(II)
AC: (2-iminemethylpyrrolyl)(2-ethyliminemethylpyrrolyl)manganese(II)
AD: (2-iminemethylpyrrolyl)(2-isopropyliminemethylpyrrolyl)manganese(II)
AE: (2-methyliminemethylpyrrolyl)(2-ethyliminemethylpyrrolyl)manganese(II)
AF: (2-methyliminemethylpyrrolyl)(2-isopropyliminemethylpyrrolyl)manganese(II)
AG: (2-iminemethylpyrrolyl)(2-tertbutyliminemethylpyrrolyl) manganese(II)
AH: (2-methyliminemethylpyrrolyl)(2-tertbutyliminemethylpyrrolyl) manganese(II)
AI: (2-ethyliminemethylpyrrolyl)(2-tertbutyliminemethylpyrrolyl)manganese(II)
AJ: Bis 2-trimethylsilylbutyliminemethylpyrrolyl manganese(II)
AK: Bis 2-trifluoromethyliminemethylpyrrolyl manganese(II)
AL: Bis 2-(2,2,2-trifluoro-N-isopropylacetimidoyl)pyrrolyl manganese(II)
AM: Bis 2-(N-isopropyliminomethyl)-5-trifluoromethylpyrrolyl manganese(II)

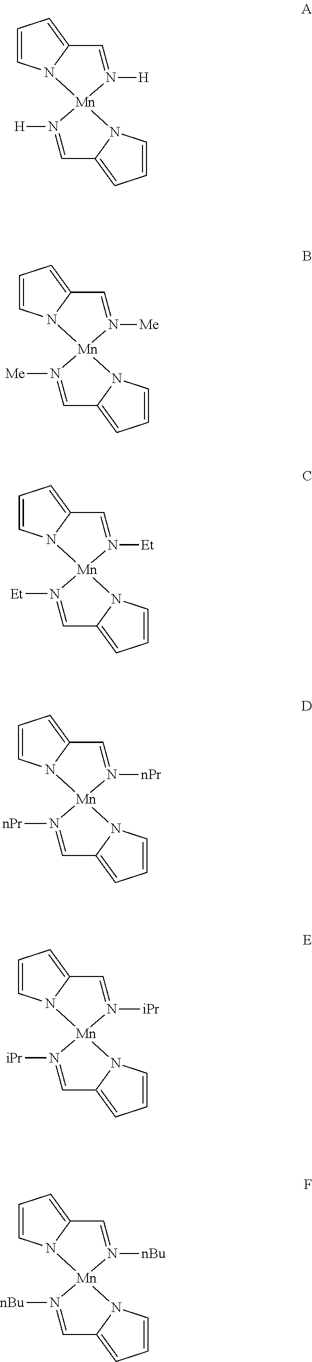

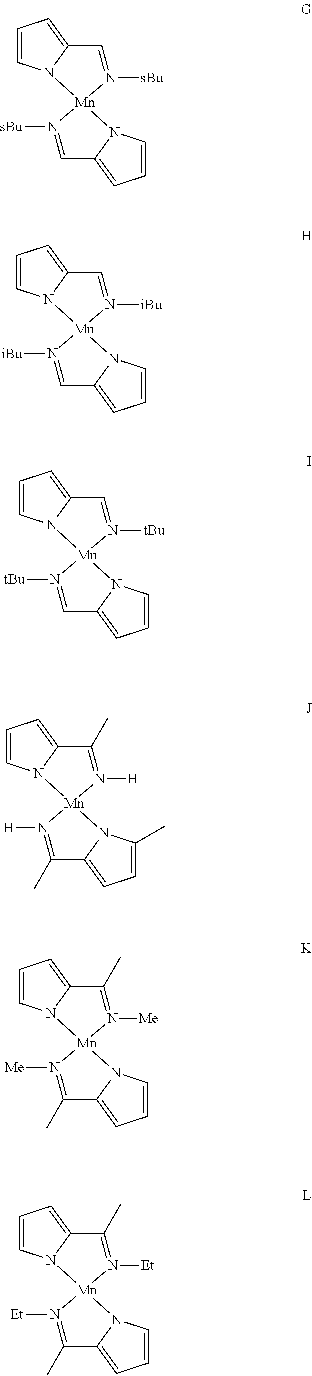

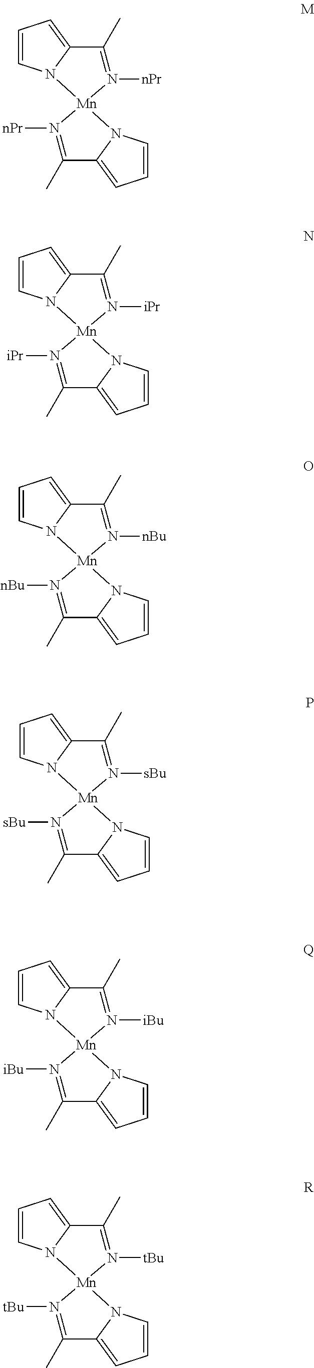

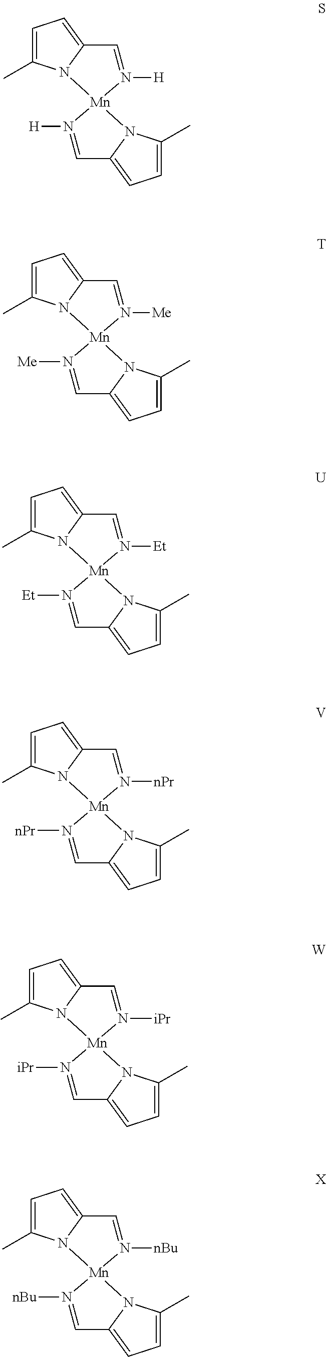

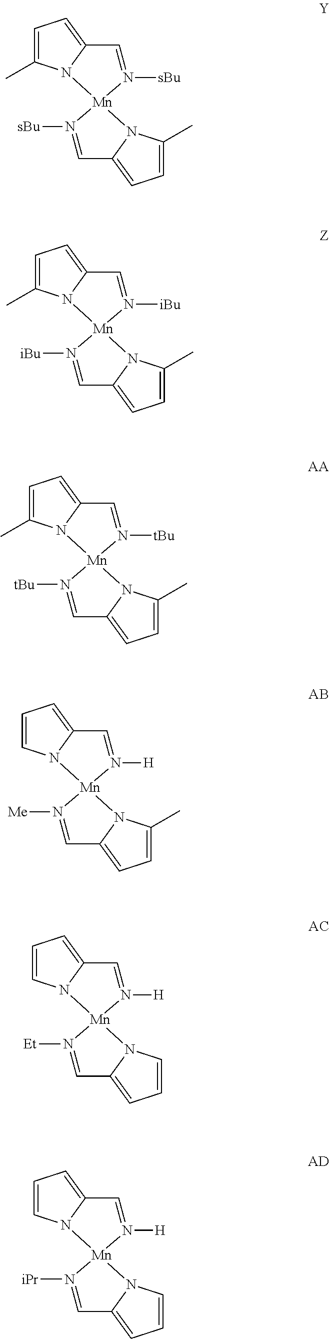

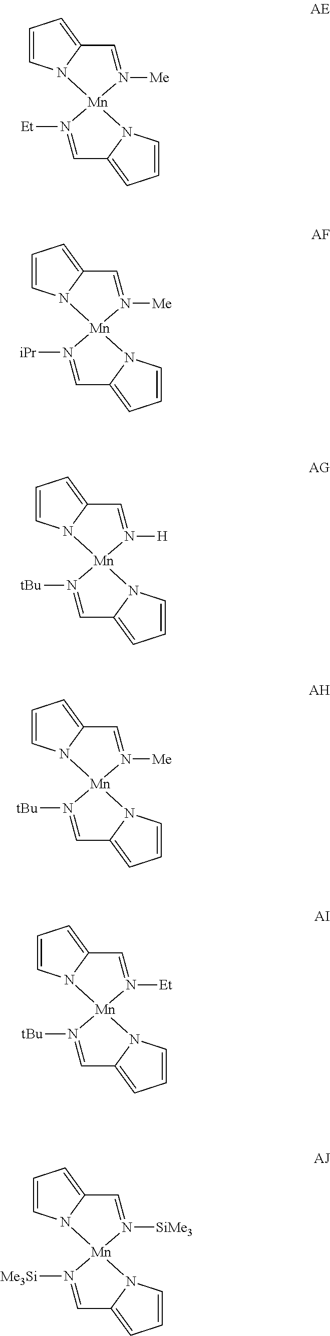

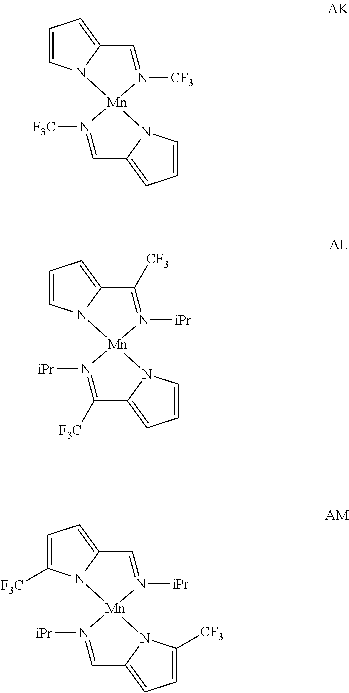

The disclosed manganese-containing precursors may be synthesized by the following methods:
Scheme-1: By reacting MnX₂, with X=Cl, Br, I or F, with 2 equivalents of Z-L, wherein Z=Li, Na, K, or Tl and L=pyrroles-2-aldiminate ligand. The reaction may occur in a polar solvent, including but not limited to THF, ether, benzene, toluene, methanol, or ethanol.

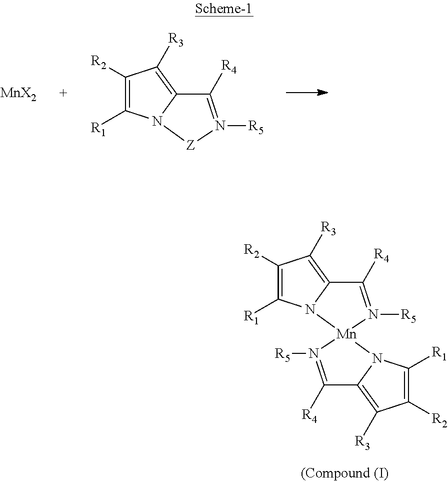

Scheme-2: By reacting MnX₂, with X=OAc, OMe, OEt, with 2 equivalents of pyrroles-2-aldiminate ligand. The reaction may occur in a polar solvent, including but not limited to THF, ether, benzene, toluene, methanol, or ethanol.

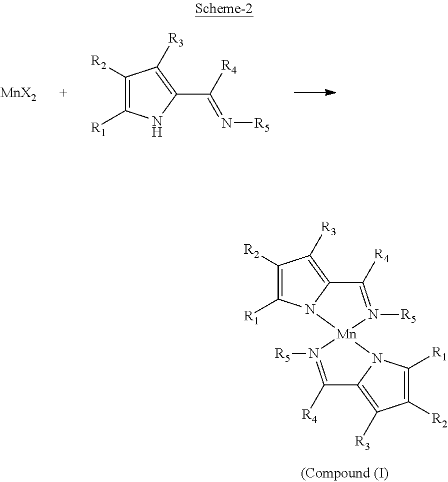

The synthesis methods may further include removing the polar solvent, adding a second solvent (pentane, hexane, heptane, benzene, toluene for instance) to form a solution, filtering the solution; and removing the second solvent to form the disclosed manganese-contained precursor. The synthesis method may further comprise distilling or sublimating the disclosed manganese-containing precursor having the formula.

The disclosed manganese-containing precursors may be used to form a magnesium-containing layer on a substrate. The resulting products may be useful in the semiconductor, photovoltaic, flat panel, or LCD-TFT devices.

The disclosed manganese-containing precursors may be used to deposit a thin film using any deposition methods known to those of skill in the art. Examples of suitable deposition methods include without limitation, conventional chemical vapor deposition (CVD), low pressure chemical vapor deposition (LPCVD), plasma enhanced chemical vapor depositions (PECVD), atomic layer deposition (ALD), pulsed chemical vapor deposition (PCVD), plasma enhanced atomic layer deposition (PEALD), or combinations thereof.

The disclosed manganese-containing precursors may be supplied either in neat form or in a blend with a suitable solvent, such as ethyl benzene, xylene, mesitylene, decane, dodecane. The disclosed precursors may be present in varying concentrations in the solvent.

The neat or blended precursor is introduced into a reactor in vapor form by conventional means, such as tubing and/or flow meters. The precursor in vapor form may be produced by vaporizing the neat or blended precursor solution through a conventional vaporization step such as direct vaporization, distillation, or by bubbling. The neat or blended precursor may be fed in liquid state to a vaporizer where it is vaporized before it is introduced into the reactor. Alternatively, the neat or blended precursor may be vaporized by passing a carrier gas into a container containing the precursor or by bubbling the carrier gas into the precursor. The carrier gas may include, but is not limited to, Ar, He, N₂, and mixtures thereof. Bubbling with a carrier gas may also remove any dissolved oxygen present in the neat or blended precursor solution. The carrier gas and precursor are then introduced into the reactor as a vapor.

If necessary, the container of disclosed precursor may be heated to a temperature that permits the precursor to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of precursor vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates onto which the thin films will be deposited. The one or more substrates may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. The substrate may also have one or more layers of differing materials already deposited upon it from a previous manufacturing step.

The temperature and the pressure within the reactor are held at conditions suitable for ALD or CVD depositions. In other words, conditions within the chamber are such that at least part of the vaporized precursor is deposited onto the substrate to form a manganese-containing film. For instance, the pressure in the reactor may be held between about 1 Pa and about 10⁵ Pa, or preferably between about 25 Pa and 10³ Pa, as required per the deposition parameters. Likewise, the temperature in the reactor may be held between about 100° C. and about 500° C., preferably between about 150° C. and about 350° C.

In addition to the disclosed precursor, a reactant may also be introduced into the reactor. The reactant may be an oxidizing gas such as one of O₂, O₃, H₂O, H₂O₂, NO, NO₂, N₂O, carboxylic acids, formic acid, acetic acid, propionic acid, oxygen radicals thereof such as O. or OH., and mixtures thereof. Preferably, the oxidizing gas may be O₂, O₃, H₂O, NO, N₂O, oxygen radicals thereof, and mixtures thereof.

Alternatively, the reactant may be a reducing gas such as one of H₂, NH₃, SiH₄, Si₂H₆, Si₃H₈, (CH₃)₂SiH₂, (C₂H₅)₂SiH₂, N(SiH₃)₃, (CH₃)SiH₃, (C₂H₅)SiH₃, phenyl silane, N₂H₄, N(CH₃)H₂, N(C₂H₅)H₂, N(CH₃)₂H, N(C₂H₅)₂H, N(CH₃)₃, N(C₂H₅)₃, (SiMe₃)₂NH, (CH₃)HNNH₂, (CH₃)₂NNH₂, phenyl hydrazine, B₂H₆, 9-borabicyclo[3,3,1]nonane, dihydrobenzenfuran, pyrazoline, trimethylaluminium, dimethylzinc, diethylzinc, radical species thereof, and mixtures thereof. Preferably, the reducing gas may be H₂, NH₃, SiH₄, Si₂H₆, Si₃H₈, SiH₂Me₂, SiH₂Et₂, N(SiH₃)₃, hydrogen radicals thereof, and mixtures thereof.

The reactant may be treated by a plasma, in order to decompose the reactant into its radical form. N₂ may also be utilized as a reducing gas when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reaction chamber, for instance, in a remotely located plasma system. One of skill in the art will recognize methods and apparatus suitable for such plasma treatment.

The vapor deposition conditions within the chamber allow the disclosed precursor and the reactant to react and form a manganese-containing film on the substrate. In some embodiments, Applicants believe that plasma-treating the reactant may provide the reactant with the energy needed to react with the disclosed precursor.

Depending on what type of film is desired to be deposited, a second precursor may be introduced into the reactor. The second precursor comprises another element source, such as copper, praseodymium, manganese, ruthenium, titanium, tantalum, bismuth, zirconium, hafnium, lead, niobium, magnesium, aluminum, lanthanum, or mixtures of these. When a second element containing precursor is utilized, the resultant film deposited on the substrate may contain at least two different elements.

The disclosed precursor and any optional reactants or precursors may be introduced sequentially (as in ALD) or simultaneously (as in CVD) into the reaction chamber. The reaction chamber may be purged with an inert gas between the introduction of the precursor and the introduction of the reactant. Alternatively, the reactant and the precursor may be mixed together to form a reactant/precursor mixture, and then introduced to the reactor in mixture form.

The vaporized precursor and the reactant may be pulsed sequentially or simultaneously (e.g. ALD or pulsed CVD) into the reactor. Each pulse of precursor may last for a time period ranging from about 0.01 seconds to about 10 seconds, alternatively from about 0.3 seconds to about 3 seconds, alternatively from about 0.5 seconds to about 2 seconds. In another embodiment, the reactant may also be pulsed into the reactor. In such embodiments, the pulse of each gas/vapor may last for a time period ranging from about 0.01 seconds to about 10 seconds, alternatively from about 0.3 seconds to about 3 seconds, alternatively from about 0.5 seconds to about 2 seconds.

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD type process, the vapor phase of the disclosed precursor and a reactant are simultaneously introduced into the reactor. The two react to form the resulting thin film. When the reactant in this exemplary CVD process is treated with a plasma, the exemplary CVD process becomes an exemplary PECVD process. The co-reactant may be treated with plasma prior or subsequent to introduction into the chamber.

In one non-limiting exemplary ALD type process, the vapor phase of the disclosed precursor is introduced into the reactor, where it contacts the substrate. Excess precursor may then be removed from the reactor by purging and/or evacuating the reactor. A reducing gas (for example, H₂) is introduced into the reactor where it reacts with the absorbed precursor in a self-limiting manner. Any excess reducing gas is removed from the reactor by purging and/or evacuating the reactor. If the desired film is a manganese film, this two-step process may provide the desired film thickness or may be repeated until a film having the necessary thickness has been obtained.

Alternatively, if the desired film is a dimer film, the two-step process above may be followed by introduction of the vapor of a second element-containing precursor into the reactor. The second element-containing precursor will be selected based on the nature of the dimer film being deposited. After introduction into the reactor, the second element-containing precursor is contacted with the substrate. Any excess second element-containing precursor is removed from the reactor by purging and/or evacuating the reactor. Once again, a reducing gas may be introduced into the reactor to react with the second element-containing precursor. Excess reducing gas is removed from the reactor by purging and/or evacuating the reactor. If a desired film thickness has been achieved, the process may be terminated. However, if a thicker film is desired, the entire four-step process may be repeated. By alternating the provision of the disclosed manganese-containing precursor, second element-containing precursor, and reactant, a film of desired composition and thickness can be deposited.

When the reactant in this exemplary ALD process is treated with a plasma, the exemplary ALD process becomes an exemplary PEALD process. The reactant may be treated with plasma prior or subsequent to introduction into the chamber.

The manganese-containing films resulting from the processes discussed above may include a pure manganese (Mn), manganese silicate (MnₖSiₗ), manganese oxide (MnₙOₘ) or manganese oxynitride (MnₓN_{y}O_{z}) film wherein k, l, m, n, x, y, and z are integers which inclusively range from 1 to 6. One of ordinary skill in the art will recognize that by judicial selection of the appropriate disclosed precursor, optional second element-containing precursors, and reactant species, the desired film composition may be obtained.

### EXAMPLES

The following examples illustrate experiments performed in conjunction with the disclosure herein. The examples are not intended to be all inclusive and are not intended to limit the scope of disclosure described herein.

### Example 1

### Synthesis of Bis 2-methyliminemethylpyrrolyl manganese(II)

1.72 g (15.89 mmol) 2-methyliminemethylpyrrole and 10 mL THF were introduced under nitrogen to a schlenk flask. 401 mg (15.89 mmol) NaH (95% w/w) was introduced slowly at room temperature. The mixture was stirred for 1 hour at room temperature.

1.0 g (7.95 mmol) MnCl₂ was introduced at once to the mixture and the mixture stirred overnight at room temperature. A brown solution with white suspension was formed. The solution was filtered over a diatomaceous earth filter medium sold by Kanto Chemical Co. The solvent was then removed under vacuum. The solid was washed with toluene (6×5 mL) until the toluene fraction remained uncolored. The yellow solid was dried under vacuum and sublimed at T>200° C. @ 50 mTorr. 460 mg (21% mol/mol yield) of a yellow solid was recovered. MP=187° C.

### Example 2

### Synthesis of Bis 2-ethyliminemethylpyrrolyl manganese(II)

1.94 g (15.89 mmol) of 2-ethyliminemethylpyrrole and 10 mL of THF was introduced to a schlenk flask under nitrogen. 401 mg (15.89 mmol) NaH (95% w/w) was introduced slowly at room temperature. The mixture was stirred for 1 hour at room temperature.

1.0 g (7.95 mmol) MnCl₂ was introduced at once and the mixture stirred overnight at room temperature. A brown solution with white suspension was formed. The solution was filtered over a diatomaceous earth filter medium sold by Kanto Chemical Co. The solvent was then removed under vacuum. The solid was dried under vacuum and sublimed twice at 160° C. @ 50 mTorr. 640 mg (27% mol/mol yield) of a yellow-orange solid was recovered. MP=128° C.

### Example 3

### Synthesis of bis 2-isopropyliminemethylpyrrolyl manganese(II)

2.164 g (15.89 mmol) of 2-isopropyliminemethylpyrrole and 10 mL of THF were introduced to a schlenk flask under nitrogen. 401 mg (15.89 mmol) of NaH (95% w/w) was introduced slowly at room temperature. The mixture was stirred for 1 hour at room temperature.

1.0 g (7.95 mmol) of MnCl₂ was introduced at once and the mixture stirred overnight at room temperature. A brown solution with white suspension was formed. The solution was filtered over a diatomaceous earth filter medium sold by Kanto Chemical Co. The solvent was then removed under vacuum. The solid was dried under vacuum and sublimed twice at 140° C. @ 50 mTorr. 160 mg (6% mol/mol yield) of a yellow solid was recovered. MP=104° C.

### Example 4

### Synthesis of bis 2-tertbutyliminemethylpyrrolyl manganese(II)

1.40 g (9.32 mmol) of 2-tertbutyliminemethylpyrrole and 10 mL of THF were introduced to a schlenk flask under nitrogen. 235 mg (9.32 mmol) of NaH (95% w/w) was introduced slowly at room temperature. The mixture was stirred for 1 hour at room temperature.

586 mg (4.65 mmol) of MnCl₂ was introduced at once and the mixture stirred overnight at room temperature. A brown solution with white suspension was formed. The solution was filtered over a diatomaceous earth filter medium sold by Kanto Chemical Co. The solvent was then removed under vacuum. The solid was dried under vacuum and sublimed twice at 140° C. @ 50 mTorr. 260 mg (16% mol/mol yield) of a yellow solid was recovered. MP=166° C.

### Example 5

### Thermogravimetric Analysis (TGA) of bis 2-alkyliminemethylpyrrolyl manganese(II) Precursors

TGA testing was performed using a TGA/SDTA851 from Mettler Toledo in a glove box under pure nitrogen atmosphere. A nitrogen flow rate of 100 sccm was applied. The temperature was increased by 10° C./min under atmospheric or vacuum (20 mbar) conditions.

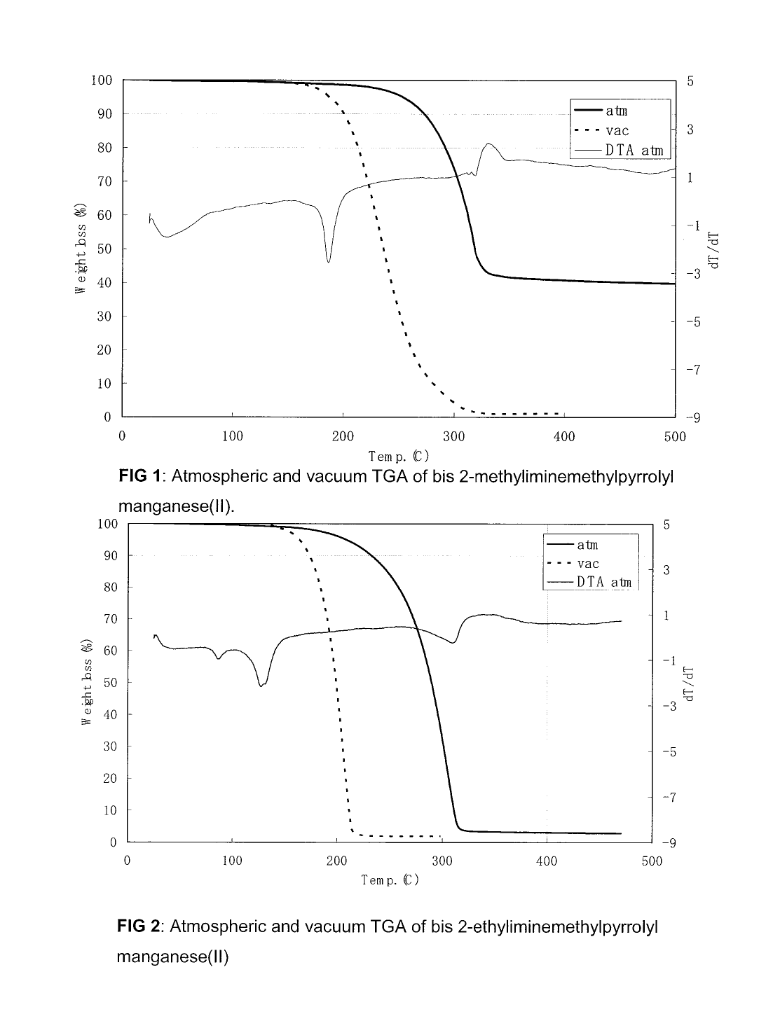

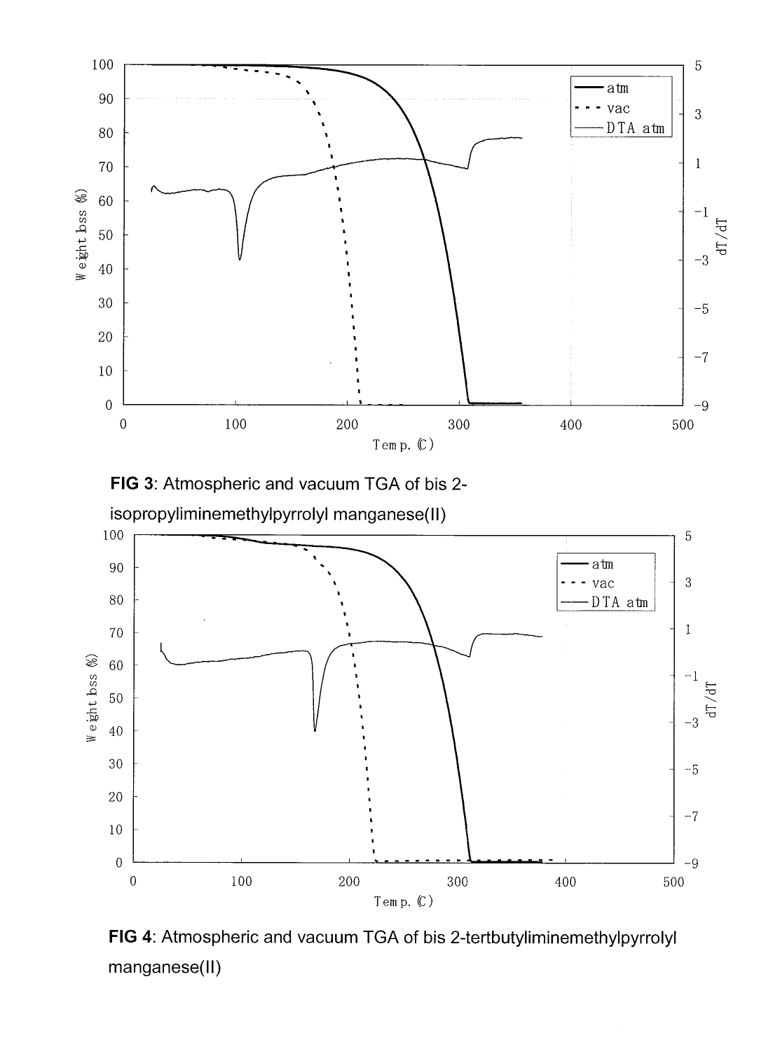

The precursors of Examples 1-4 were fully vaporized under both atmospheric and vacuum condition. A graph of the results is provided in FIGS. 1-4. Differential Thermal Analysis (DTA) was also performed under atmospheric conditions on the precursors of Examples 1-4 and those results are included in the graphs of FIGS. 1-4. Bis 2-isopropyliminemethylpyrrolyl manganese(II) (R₁ to R₄=H and R₅=iPr) (FIG. 3) and bis 2-tertbutyl-iminemethylpyrrolyl manganese(II) (R₁ to R₄═H and R₅=tBu) (FIG. 4) were found to have a clean evaporation under atmospheric condition with an end of evaporation temperature around 310° C.

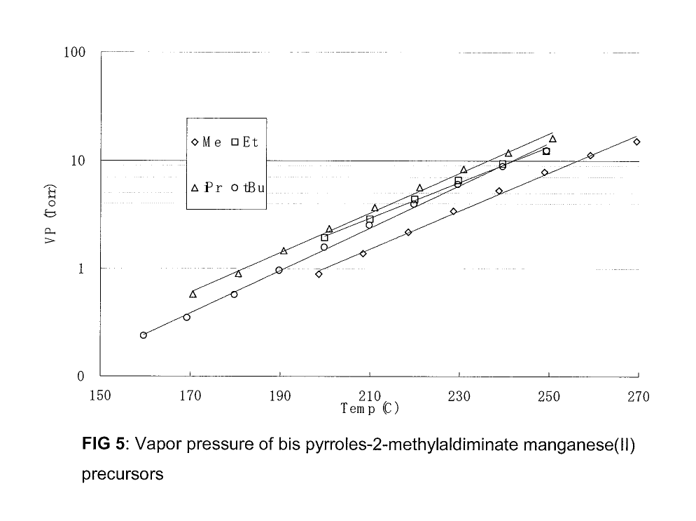

The vapor pressures for the precursors of Examples 1-4 are provided in FIG. 5. The vapor pressure of Bis 2-isopropyliminemethyl-pyrrolyl manganese(II) (R₁ to R₄=H and R₅=iPr) is about 1 Torr @ 180° C., which makes this precursor suitable for ALD applications.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1. A process for the deposition of a manganese-containing film on a substrate, comprising the steps of:
a) providing a reactor and at least one substrate disposed in the reactor;
b) introducing into the reactor a vapor of at least one manganese-containing precursor having the formula: 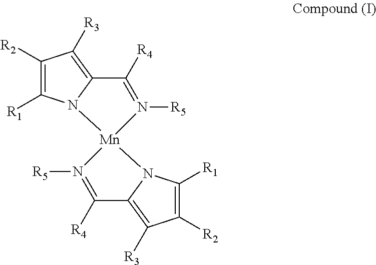
wherein each R¹ through R⁵ is independently selected from H; C₁-C₄ linear or branched alkyl group; C₁-C₄ linear, branched, or cyclic alkylsilyl group; C₁-C₄ alkylamino group; and a C₁-C₄ linear, branched, or cyclic fluoroalkyl group;
c) depositing at least part of the vapor onto the substrate to form the manganese-containing film.

2. The method of claim 1, further comprising maintaining the reactor at a temperature between about 100° C. to about 500° C.

3. The method of claim 1, further comprising maintaining the reactor at a pressure between about 1 Pa and about 10⁵ Pa.

4. The method of claim 1, wherein the manganese-containing precursor is selected from the group consisting of:
Bis 2-iminemethylpyrrolyl manganese(II)
Bis 2-methyliminemethylpyrrolyl manganese(II)
Bis 2-ethyliminemethylpyrrolyl manganese(II)
Bis 2-isopropyliminemethylpyrrolyl manganese(II)
Bis 2-npropyliminemethylpyrrolyl manganese(II)
Bis 2-nbutyliminemethylpyrrolyl manganese(II)
Bis 2-secbutyliminemethylpyrrolyl manganese(II)
Bis 2-isobutyliminemethylpyrrolyl manganese(II)
Bis 2-tertbutyliminemethylpyrrolyl manganese(II) and
Bis 2-trimethylsilylbutyliminemethylpyrrolyl manganese(II).

5. The method of claim 1, further comprising introducing at least one reactant into the reactor.

6. The method of claim 5, wherein the reactant is selected from the group consisting of H₂; NH₃; SiH₄; Si₂H₆; Si₃H₈; SiH₂Me₂, SiH₂Et₂, N(SiH₃)₃, hydrogen radicals; and mixtures thereof.

7. The method of claim 5, wherein the reactant is selected from the group consisting of: O₂; O₃; H₂O; NO; N₂O, oxygen radicals; and mixtures thereof.

8. The method of claim 5, wherein the manganese-containing precursor and the reactant are introduced into the chamber substantially simultaneously, and the chamber is configured for chemical vapor deposition.

9. The method of claim 5, wherein the manganese-containing precursor and the reactant are introduced into the chamber sequentially, and the chamber is configured for atomic layer deposition.

10. The method of claim 8, wherein the chamber is configured for plasma enhanced chemical vapor deposition.

11. A method of synthesizing a manganese-containing precursor having the structure: 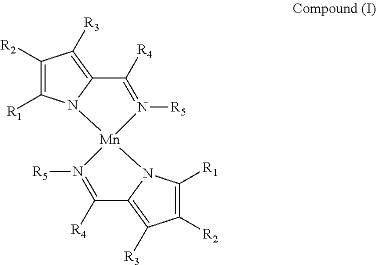
wherein each R¹-R⁵ is independently selected from H; C₁-C₄ linear or branched alkyl group; C₁-C₄ linear, branched, or cyclic alkylsilyl group; C₁-C₄ alkylamino group; and C₁-C₄ linear or branched fluoroalkyl group; the method comprising:
reacting MnX₂, with X=Cl, Br, I or F, with 2 equivalents of Z-L, wherein Z=Li, Na, K, and Tl and L=pyrroles-2-aldiminate ligand.

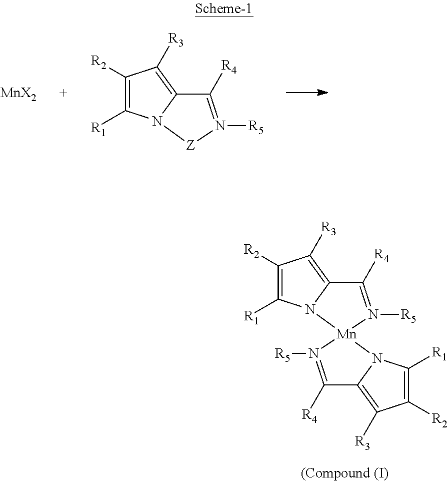

12. A method of synthesizing a manganese-containing precursor having the structure: 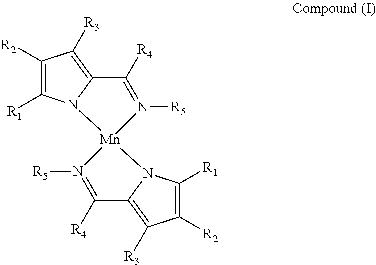
wherein each R¹-R⁵ is independently selected from H; C₁-C₄ linear, branched, or cyclic alkyl group; C₁-C₄ linear, branched, or cyclic alkylsilyl group; C₁-C₄ alkylamino group; and C₁-C₄ linear, branched, or cyclic fluoroalkyl group; the method comprising:
reacting MnX₂, with X=OAc, OMe, OEt, with 2 equivalents of pyrroles-2-aldiminate ligand.

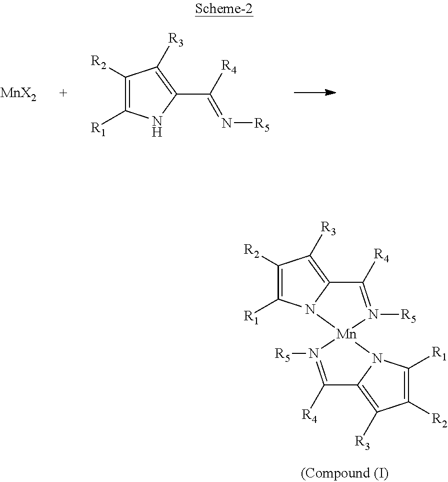

13. The method of claim 11, wherein the reacting step occurs in a polar solvent, further comprising:
removing the polar solvent;
forming a solution by adding a second solvent selected from the group consisting of pentane, hexane, benzene, and toluene;
filtering the solution; and
removing the second solvent to form the manganese-containing precursor.

14. The method of claim 13, further comprising distilling or sublimating the manganese-containing precursor.

15. The method of claim 1, wherein the manganese-containing precursor is bis 2-isopropyliminemethylpyrrolyl manganese (II).

16. The method of claim 9, wherein the chamber is configured for plasma enhanced atomic layer deposition.

17. The method of claim 8, wherein the manganese-containing precursor is bis 2-isopropyliminemethylpyrrolyl manganese (II).

18. The method of claim 9, wherein the manganese-containing precursor is bis 2-isopropyliminemethylpyrrolyl manganese (II).

19. The method of claim 12, wherein the reacting step occurs in a polar solvent, further comprising:
removing the polar solvent;
forming a solution by adding a second solvent selected from the group consisting of pentane, hexane, benzene, and toluene;
filtering the solution; and
removing the second solvent to form the manganese-containing precursor.

20. The method of claim 19, further comprising distilling or sublimating the manganese-containing precursor.
